(19) United States
(12) Patent Application Publication
(10) Pub. No.: US 2010/0072527 A1
(43) Pub. Date: Mar. 25, 2010

(54) SEMICONDUCTOR MEMORY DEVICE AND MANUFACTURING METHOD THEREOF

(75) Inventor: Tohru OZAKI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/559,469

(22) Filed: Sep. 14, 2009

(30) Foreign Application Priority Data
Sep. 24, 2008 (JP) 2008-244475

(51) Int. Cl. H01L 27/115; H01L 21/8246

(52) U.S. Cl. 257/295; 438/3; 257/E27.104; 257/E21.664

(57) ABSTRACT

A semiconductor memory device includes: a transistor on a semiconductor substrate; an interlayer dielectric film covering the transistor; a ferroelectric capacitor comprising a first upper electrode, a ferroelectric film, and a lower electrode on the interlayer dielectric film; a contact plug which is in the interlayer dielectric film and electrically connects the lower electrode to the transistor; a second upper electrode on the first upper electrode, a side surface of the second upper electrode being formed in a forward tapered shape; and an interconnection electrically connected via the second upper electrode to the first upper electrode.

### CROSS-REFERENCE TO RELATED APPLICATION

This application is based upon and claims the benefit of priority from the prior Japanese Patent Applications No. 2008-244475, filed on Sep. 24, 2008, the entire contents of which are incorporated herein by reference.

### BACKGROUND OF THE INVENTION

1. Field of the Invention

The present invention relates to a semiconductor memory device and manufacturing method thereof.

2. Related Art

Ferroelectric random access memories have been attracted attention as one of nonvolatile semiconductor memories. Further, “Series connected TC unit type ferroelectric RAM (hereinafter, also “ferroelectric RAM”)” have been developed recently.

Lower electrodes of ferroelectric capacitors are connected to cell transistors by conductive contact plugs under the ferroelectric capacitors, which is a so-called COP (Capacitor On Plug) structure. Because polarization characteristics of the ferroelectric capacitors are degraded by a reducing process of hydrogen, hydrogen barrier films are used frequently for protecting the ferroelectric capacitors from hydrogen.

Upper electrodes of the ferroelectric RAM with the COP structure are conventionally connected via contact plugs formed by burying tungsten or aluminum in contact holes (damascene process) to local interconnections. To sufficiently reduce a contact resistance between the contact plugs and the upper electrodes in spite of downscaled memory cells, the amount of over etching must be increased during a process of forming contact holes. The increased amount of over etching leads to hollowing out of the upper electrodes, and induces damage like oxygen vacancy in the ferroelectric capacitors during etching process. Such hollowing out in the upper electrodes may reduce a signal difference between data “0” and “1”.

When the contact holes are downscaled, it is difficult to bury metal in the contact holes. Although metal is probably buried in small contact holes by reflow, reflow devices and CMP (Chemical-Mechanical Polishing) devices must be provided, resulting in cost increase.

When metal is buried in the contact holes by MO-CVD, the polarization characteristics of the ferroelectric capacitors may be degraded by hydrogen, due to oxygen vacancy increasing.

### SUMMARY OF THE INVENTION

A semiconductor memory device according to an embodiment of the present invention comprises: a transistor on a semiconductor substrate; an interlayer dielectric film covering the transistor; a ferroelectric capacitor comprising a first upper electrode, a ferroelectric film, and a lower electrode on the interlayer dielectric film; a contact plug which is in the interlayer dielectric film and electrically connects the lower electrode to the transistor; a second upper electrode on the first upper electrode, a side surface of the second upper electrode being formed in a forward tapered shape; and an interconnection electrically connected via the second upper electrode to the first upper electrode.

A manufacturing method of a semiconductor memory device according to an embodiment of the present invention, comprises: forming a plurality of transistors on a semiconductor substrate; forming a first interlayer dielectric film covering the transistors; forming a plurality of first contact plugs passing through the first interlayer dielectric film to be connected to the transistors; forming a plurality of ferroelectric capacitors each of which comprises a first upper electrode, a ferroelectric film, and a lower electrode above one of the first contact plugs; forming a second interlayer dielectric film between adjacent ferroelectric capacitors; depositing a second upper electrode material on the first upper electrode and the second interlayer dielectric film; processing the second upper electrode material to form a second upper electrode on each of the first upper electrodes; forming a third interlayer dielectric film between the adjacent second upper electrodes; forming a second contact plug passing through the third and the second interlayer dielectric films to be electrically connected to the transistor; and forming an interconnection on the third interlayer dielectric film, the second upper electrode, and the second contact plug.

A manufacturing method of a semiconductor memory device according to an embodiment of the present invention, comprises: forming a plurality of transistors on a semiconductor substrate; forming a first interlayer dielectric film covering the transistors; forming a plurality of first contact plugs passing through the first interlayer dielectric film to be connected to the transistors; depositing materials of ferroelectric capacitors each of which comprises a first upper electrode, a ferroelectric film, and a lower electrode above one of the first contact plugs; depositing a second upper electrode material on the first upper electrode; depositing a mask material on the second upper electrode material; processing the mask material into a pattern of the second upper electrode; forming sidewall firms on side surfaces of the mask material and the second upper electrode; etching the materials of the ferroelectric capacitors using the mask material and the sidewall firms as a mask to form a plurality of ferroelectric capacitors.

### BRIEF DESCRIPTION OF THE DRAWINGS

FIG. 1 is a circuit diagram showing a configuration of a ferroelectric random access memory according to a first embodiment;

FIGS. 2 and 3 are cross-sectional views showing a ferroelectric RAM according to the first embodiment;

FIGS. 4A to 13B are cross-sectional views showing a manufacturing method of the first embodiment;

FIGS. 14 and 15 are cross-sectional views showing a configuration of a ferroelectric RAM according to a second embodiment;

FIGS. 16 and 17 are cross-sectional views showing a configuration of a ferroelectric RAM according to a third embodiment;

FIGS. 18A to 23B are cross-sectional views showing a manufacturing method of the third embodiment; and

FIGS. 24 and 25 are cross-sectional views showing a configuration of a ferroelectric RAM according to a fourth embodiment.

### DETAILED DESCRIPTION OF THE INVENTION

Embodiments of the present invention will be explained below in detail with reference to the accompanying drawings. Note that the invention is not limited thereto.

### First Embodiment

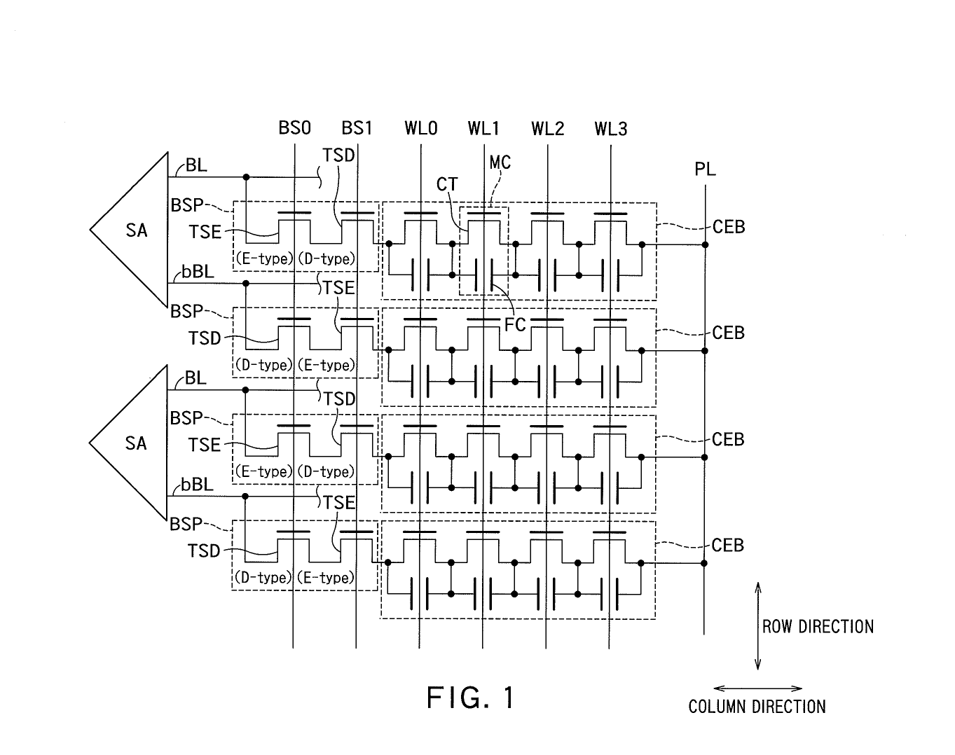

FIG. 1 is a circuit diagram showing a configuration of a ferroelectric random access memory according to a first embodiment of the present invention. The ferroelectric random access memory of the first embodiment is a Series connected TC unit type ferroelectric RAM. The ferroelectric RAM is a memory which consists of series connected memory cells each having a transistor having a source terminal and a drain terminal and a ferroelectric capacitor inbetween said two terminals.

The ferroelectric random access memory of the first embodiment includes a plurality of word lines WLi (i is an integer) extending in a row direction, a plurality of bit lines BL, bBL extending in a column direction perpendicular to the row direction, a plurality of plate lines PL extending in the row direction, and block selection parts BSP.

A memory cell MC stores binary data or multibit data in its ferroelectric capacitor. The memory cell MC is provided at the intersection of the word line WLi and the bit line BL, bBL. Each word line WLi is connected to gates of cell transistors CT arranged in the row direction. Each bit line BL, bBL is connected to sources or drains of cell transistors CT arranged in the column direction.

The ferroelectric random access memory includes a plurality of cell blocks CEB each of which is configured by serially connecting memory cells MC each of which includes a ferroelectric capacitor FC and a cell transistor TC connected to each other in parallel. One end of the cell block CEB is connected to one end of the block selection part BSP. The other end of the cell block CEB is connected to the plate line PL. The other end of the block selection part BSP is connected to the bit line BL or bBL. That is, the bit lines BL and bBL are connected via the block selection part BSP to the cell block CEB.

The block selection part BSP includes an enhancement transistor TSE and a depletion transistor TSD. The enhancement transistor TSE and the depletion transistor TSD are controlled by a block selective line BSO or BS1. Thus, the block selection part BSP can connect either the bit line BL or bBL selectively to the bit line BL or bBL.

A sense amplifier SA is connected to the bit line pair BL, bBL. The sense amplifier SA detects data from memory cells transmitted through the bit line pair BL, bBL during data reads. Further, the sense amplifier SA can apply voltage to the bit line pair BL, bBL during data writes to write data in memory cells MC. The first embodiment can be operated in a 1T1C mode or a 2T2C mode.

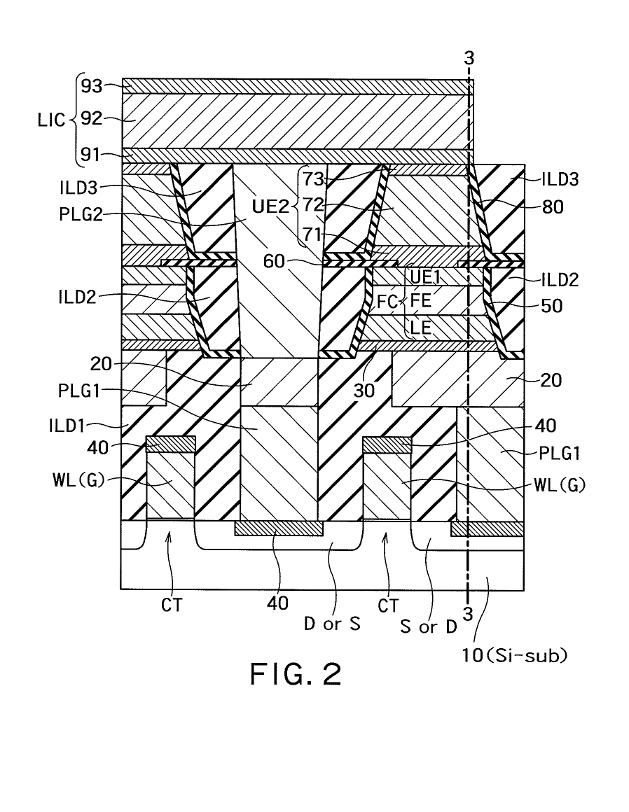

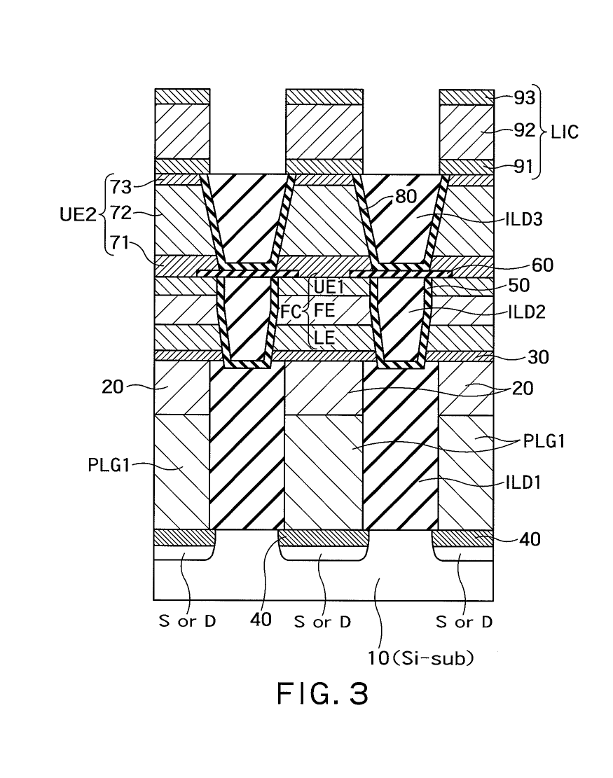

FIGS. 2 and 3 are cross-sectional views showing a ferroelectric RAM according to the first embodiment. FIG. 2 is a cross-sectional view along a direction the bit line BL extends (column direction). FIG. 3 is a cross-sectional view along a direction the word line WL extends (row direction) (cross-sectional view along line 3-3 shown in FIG. 2).

A plurality of cell transistors CT are formed on a semiconductor substrate 10. A silicide layer 40 is provided on a source S or a drain D of the cell transistor CT and a top surface of a gate electrode G. A first interlayer dielectric film ILD1 is provided in order to cover the cell transistors CT.

A first contact plug PLG1 passes through the first interlayer dielectric film ILD1 to be connected to the source S or the drain D of the cell transistor CT. A metallic plug 20 is formed on the first contact plug PLG1. A conductive hydrogen barrier film 30 is provided on the metallic plug 20. The first contact plug PLG1 and the metallic plug 20 are made of tungsten, for example. The hydrogen barrier film 30 is made of TiN or TiAlN, for example.

A lower electrode LE is provided on the hydrogen barrier film 30. The lower electrode LE is electrically connected via the hydrogen barrier film 30, the metallic plug 20, and the first contact plug PLG1 to the source S or the drain D of the cell transistor CT. A ferroelectric film FE is provided on the lower electrode LE. A first upper electrode UE1 is provided on the ferroelectric film FE. The first upper electrode UE1, the ferroelectric film FE, and the lower electrode LE constitute the ferroelectric capacitor FC. The first upper electrode UE1 is made of TiAlN or IrO₂, for example. The ferroelectric film FE is made of PZT film or SBT film, for example. The lower electrode LE is made of TiAlN or Ir or stacked layer of both materials for example.

A part of the top surface and the side surface of the ferroelectric capacitor FC are covered by dielectric hydrogen barrier films 50 and 60. The hydrogen barrier films 50 and 60 are made of alumina (Al₂O₃), for example. Other part of top surface of the ferroelectric capacitor FC is not covered by a second interlayer dielectric film ILD2 and connected to a second upper electrode UE2.

The second interlayer dielectric film ILD2 is loaded between adjacent ferroelectric capacitors FC. The second interlayer dielectric film ILD2 is formed on the side surface of the ferroelectric capacitor FC with the hydrogen barrier film 50 covering the side surface of the ferroelectric capacitor FC interposed therebetween.

The second upper electrode UE2 comprises a lower layer film 71, a core part 72, and an upper layer film 73. The lower layer film 71 is connected to the first upper electrode UE1. The lower layer film 71 and the upper layer film 73 are made of a conductive material such as TiN or TiAlN. The core part 72 is made of any viscous conductive material capable of absorbing volumetric changes in the ferroelectric capacitor FC. That is, the core part 72 is preferably made of metallic films with inherent tensile stress. The core part 72 is made of aluminum, for example. The lower layer film 71 serves as a diffusion preventing film and is provided to suppress diffusion of metal of the core part 72 toward the ferroelectric capacitor FC. The upper layer film 73 serves as a reflection preventing film and is provided to suppress inferior pattering caused by the reflection of the core part 72 during a lithography process.

The side surface of the second upper electrode UE2 is formed in a forward tapered shape like the ferroelectric capacitor FC. This is because the second upper electrode UE2 is not a metallic plug buried by a damascene process but a laminated layer obtained by processing the deposited lower layer film 71, the core part 72, and the upper layer film 73 using lithography and RIE (Reactive Ion Etching).

According to the damascene process, contact holes are formed, metal is loaded in the contact holes, and the loaded metal is flattened, so that contact plugs are formed. The contact holes are formed by lithography and etching. At this time, the side surface of the contact hole is usually formed in a reverse tapered shape.

The second upper electrode UE2 of the first embodiment is formed by etching the laminated film without using the damascene process, like the ferroelectric capacitor FC. Thus, the side surface of the second upper electrode UE2 is formed in a forward tapered shape.

A hydrogen barrier film 80 is formed on the side surface of the second upper electrode UE2. A third interlayer dielectric film ILD3 is loaded between adjacent second upper electrodes UE2.

A second contact plug PLG2 passes through the third interlayer dielectric film ILD3 and the second interlayer dielectric film ILD2 to be connected to the metallic plug 20. A local interconnection LIC is provided on the third interlayer dielectric film ILD3, the second upper electrode UE2, and the second contact plug PLG2. The local interconnection LIC comprises a lower layer film 91, a core part 92, and an upper layer film 93. The lower layer film 91 and the upper layer film 93 are made of TiN or TiAlN, for example. The core part 92 is made of a low resistance interconnection material such as copper or aluminum. The lower layer film 91 serves as a diffusion preventing film and is provided to suppress the diffusion of metal of the core part 92 toward the second upper electrode UE2 and the ferroelectric capacitor FC. The upper layer film 93 serves as a reflection preventing film and is provided to suppress inferior patterning caused by the reflection of the core part 92 during a lithography process.

The first upper electrode UE1 of the ferroelectric capacitor FC is electrically connected via the second upper electrode UE2, the local interconnection LIC, the contact plugs PLG1 and PLG2, and the metallic plug 20 to either the source S or the drain D of the cell transistor CT. The first upper electrodes UE1 of two ferroelectric capacitors adjacent to each other in a direction the bit line BL extends are connected to each other by the local interconnection LIC.

Meanwhile, the first contact plug PLG1 and the metallic plug connected to the lower electrode LE of the ferroelectric capacitor FC electrically connect the lower electrodes LE of the two ferroelectric capacitor FC adjacent to each other in the extending direction of the bit line BL to the other of the source S and the drain D of the cell transistor CT. In this way, the ferroelectric RAM is formed.

In the first embodiment, the contact plug is not provided on the first upper electrode UE1 of the ferroelectric capacitor FC. Instead, the pillar-shaped second upper electrode UE2 is provided. When the contact plug is conventionally formed on the first upper electrode UE1, a contact hole must be formed in a thick interlayer dielectric film. At this time, the first upper electrode is hollowed out by over etching. This is because the amount of over etching must be increased as the film thickness of material to be etched is increased.

In contrast to the conventional technique, according to the first embodiment, to connect the second upper electrode UE2 to the first upper electrode UE1, the hydrogen barrier film 60 much thinner than the interlayer dielectric film is merely etched. Thus, the top surface of the first upper electrode UE1 is hardly hollowed out. As a result, the deterioration of the signal difference between the data “0” and “1” can be suppressed.

The second upper electrode UE2 of the first embodiment does not use the damascene process. Thus, devices for burying metals in contact holes with high aspect ratio are not necessary, resulting in suppressed manufacturing costs.

Further, if MO-CVD (Metalorganic-Chemical Vapor Deposition) is used for burying metals in contact holes, a large amount of hydrogen is generated. Hydrogen degrades the polarization characteristics of ferroelectric materials. Because a process of burying metals in contact holes is not provided in the first embodiment, however, MO-CVD is not required for forming the second upper electrode UE2. Thus, hydrogen is not generated when the second upper electrode UE2 is formed and the deterioration of polarization characteristics of the ferroelectric capacitor FC can be suppressed.

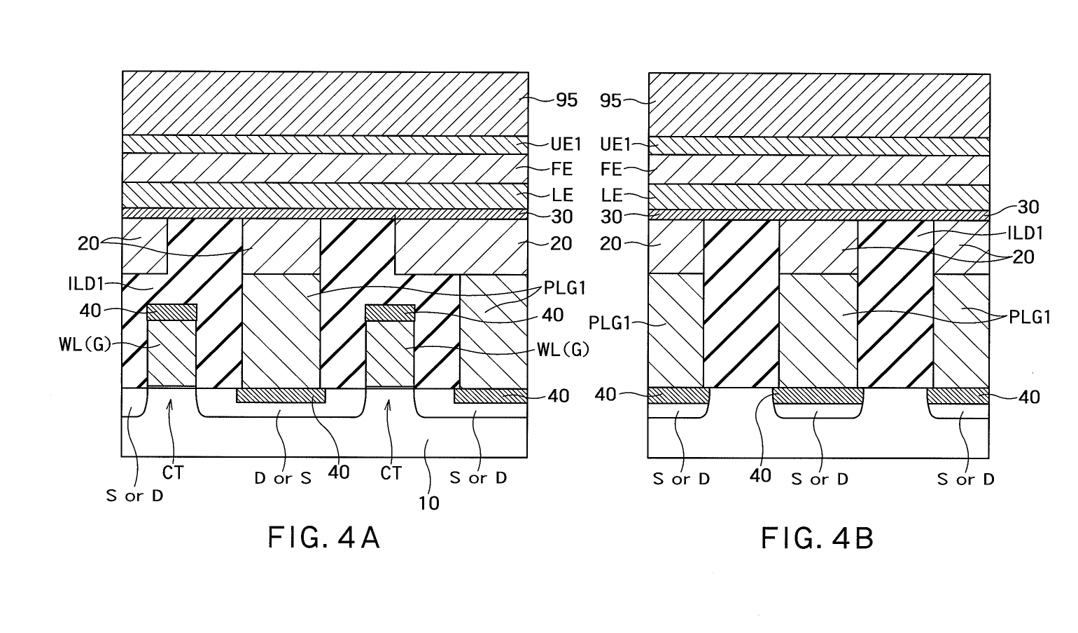

FIGS. 4A to 13B are cross-sectional views showing a manufacturing method of the first embodiment. FIGS. 4 to 13 with a character A attached thereto show cross-sections along the bit line BL (corresponding to FIG. 2). FIGS. 4 to 13 with a character B attached thereto show cross-sections along the word line WL (corresponding to FIG. 3).

As shown in FIGS. 4A and 4B, a plurality of cell transistors CT are formed on the silicon substrate 10. The word line WL also serves as a gate electrode G for the cell transistor CT. The silicide layer 40 is formed on the gate electrode G, the source S, and the drain D. The first interlayer dielectric film ILD1 is then deposited in order to cover the cell transistors CT. After the first interlayer dielectric film ILD1 is flattened, the first contact plug PLG1 is formed in the first interlayer dielectric film ILD1 by the damascene process. The first contact plug PLG1 is connected to a diffusion layer of the source S or the drain D. Further, an interlayer dielectric film is deposited and the metallic plug 20 is formed in that interlayer dielectric film by the damascene process. The metallic plug 20 is formed on the first contact plug PLG1.

The material for the hydrogen barrier film 30 (e.g., TiN or TiAlN) is deposited on the metallic plug 20. Materials for the lower electrode LE (e.g., TiAlN or Ir), the ferroelectric film FE (PZT film or SBT film), and the first upper electrode UE1 (e.g., TiAlN or IrO₂) are deposited successively on the hydrogen barrier film 30. A mask material 95 is further deposited on the material of the first upper electrode UE1. The mask material 95 is made of Ai₂O₃ or TEOS, for example. Thus, configurations shown in FIGS. 4A and 4B are obtained.

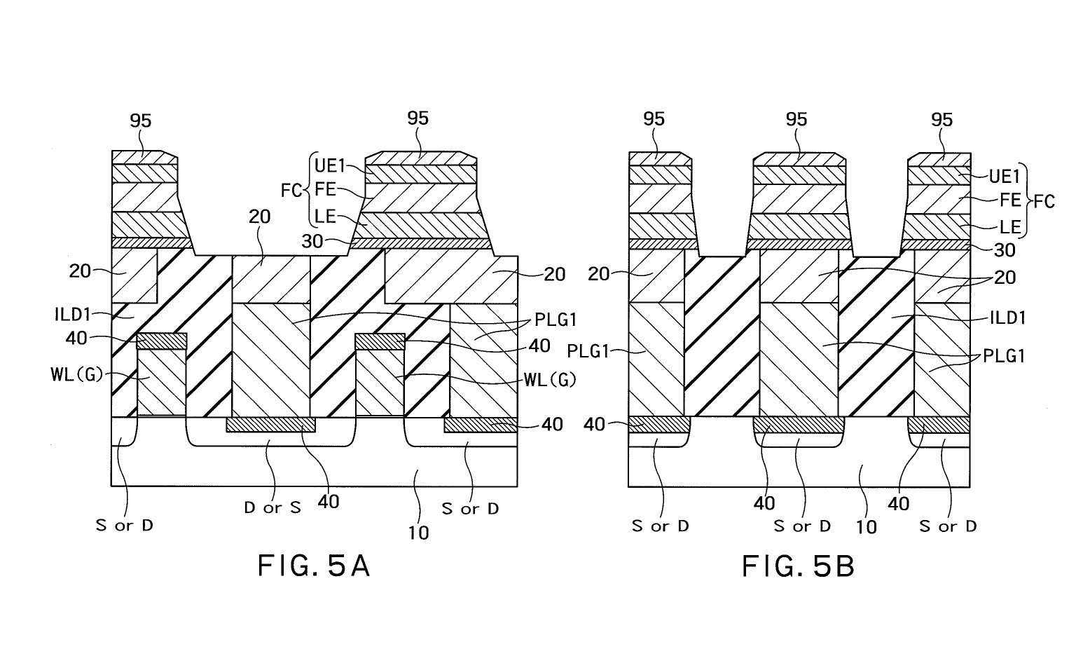

The mask material 95 is then processed in a pattern of the ferroelectric capacitor FC by lithography and RIE. The mask material 95 is processed in a pattern of the first upper electrode UE1. The materials for the first upper electrode UE1, the ferroelectric film FE, the lower electrode LE, and the hydrogen barrier film 30 are etched with RIE by using the mask material 95 as a mask. The ferroelectric capacitor FC is thus formed, as shown in FIGS. 5A and 5B. The top surface of the metallic plug 20 is exposed at the same time.

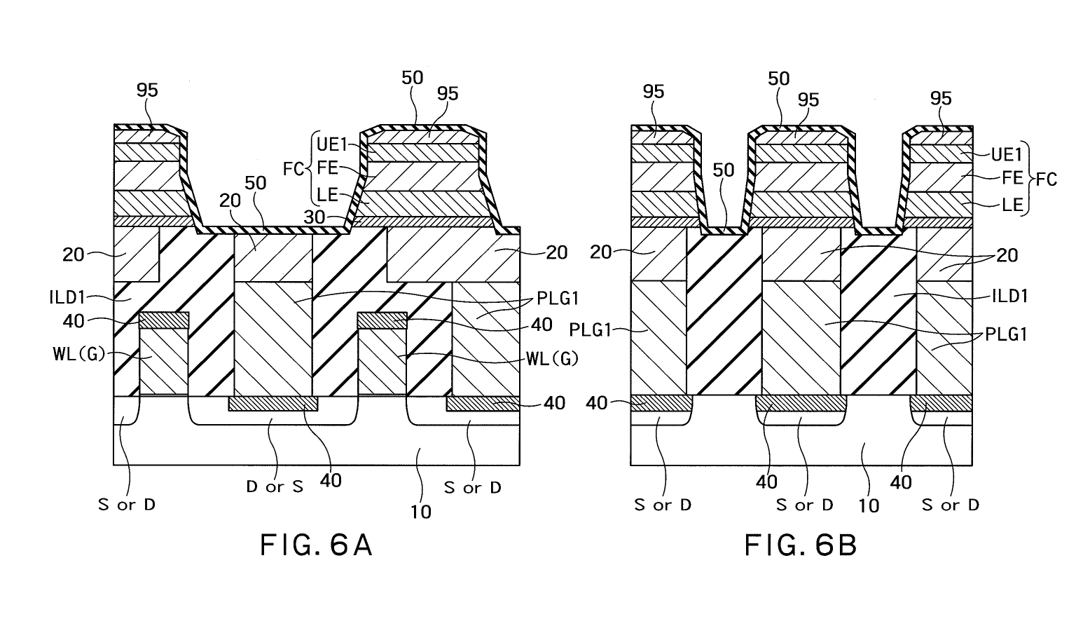

Next, as shown in FIGS. 6A and 6B, the hydrogen barrier film 50 (e.g., Al₂O₃) is deposited in order to cover the mask material 95, the side surface of the ferroelectric capacitor FC, the first interlayer dielectric film ILD1, and the metallic plug 20.

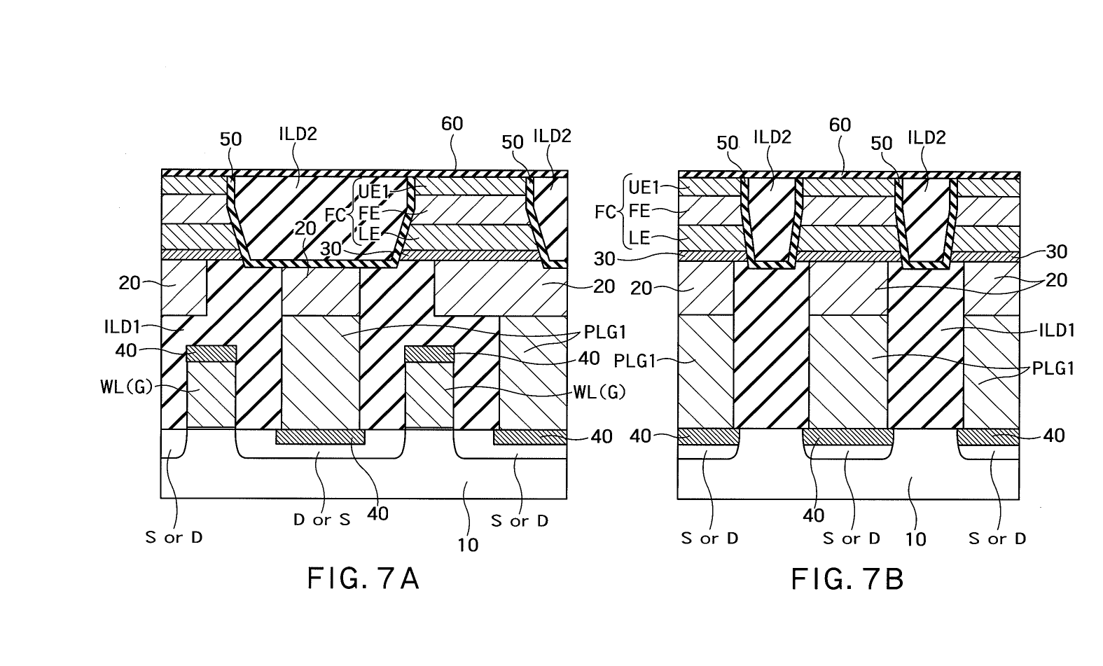

The second interlayer dielectric film ILD2 is deposited on the hydrogen barrier film 50 and then flattened by CMP. The second interlayer dielectric film ILD2 is ground until the top surface of the first upper electrode UE1 is exposed. As shown in FIGS. 7A and 7B, the hydrogen barrier film 60 (e.g., Al₂O₃) is deposited on the first upper electrode UE1 and the second interlayer dielectric film ILD2.

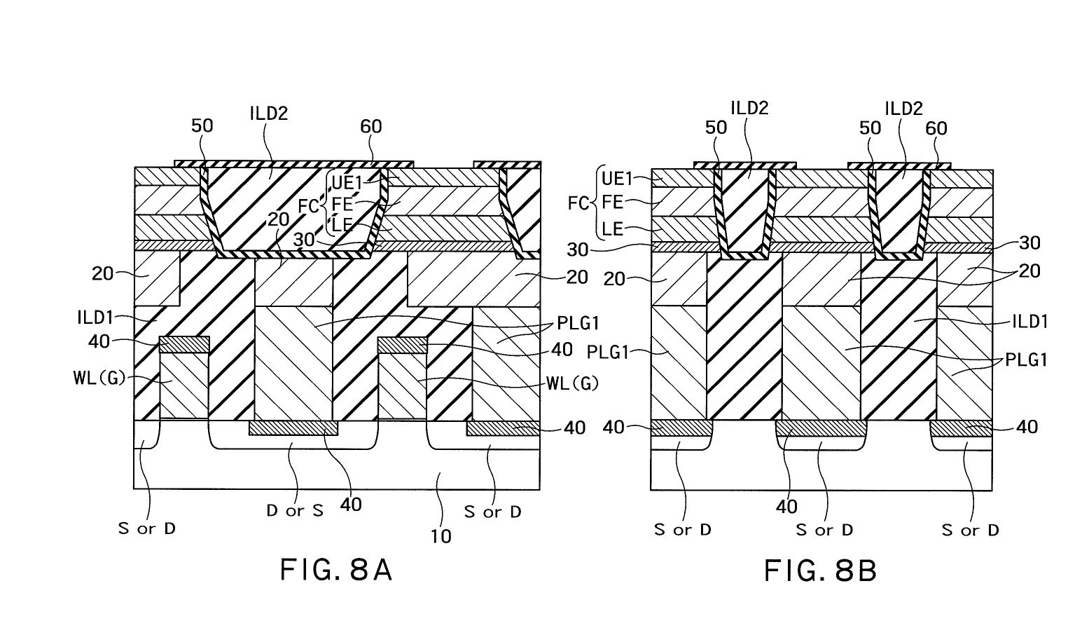

The hydrogen barrier film 60 at a part of top surface of the first upper electrode UE1 is then removed by lithography and RIE as shown in FIGS. 8A and 8B. As a result, a part of top surface of the first upper electrode UE1 is exposed. Instead of RIE which is anisotropic etching, isotropic etching such as CDE (Chemical Dry Etching) or wet etching can be used. This is because the hydrogen barrier film 60 is so much thinner than the interlayer dielectric film that side etch is negligibly small. Accordingly, the amount of over etching with respect to the first upper electrode UE1 is reduced as compared to conventional cases.

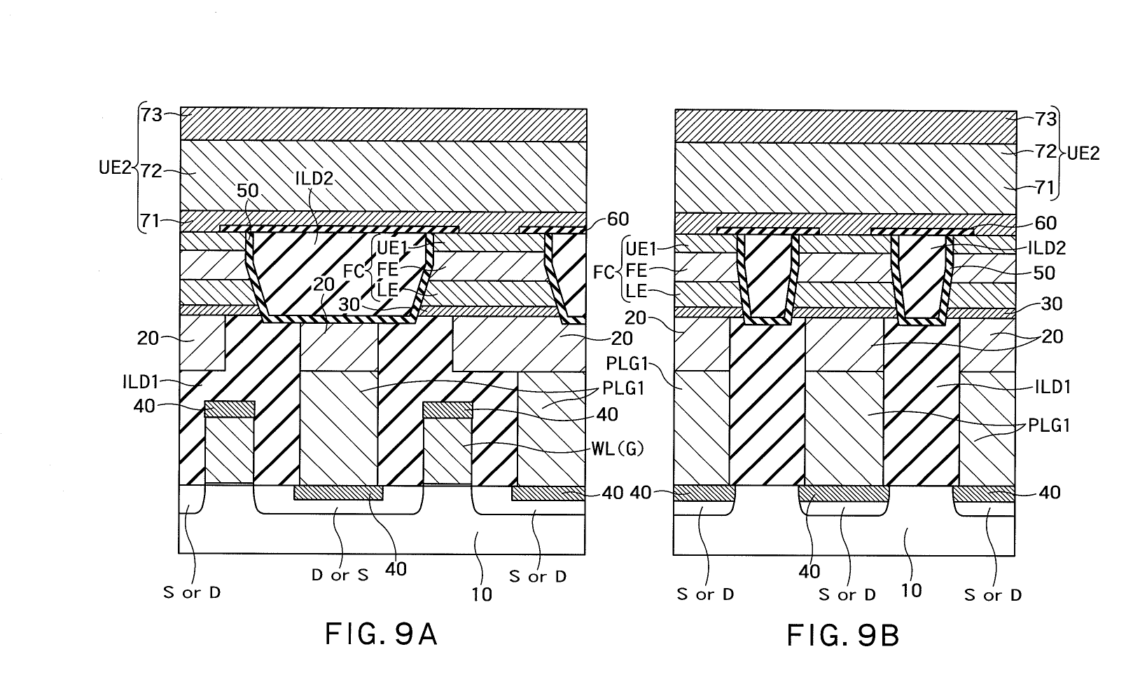

As shown in FIGS. 9A and 9B, the material for the lower layer film 71 of the second upper electrode UE2 (e.g., TiN or TiAlN) is deposited on the first upper electrode UE1 and the hydrogen barrier film 60. The material for the core part 72 (e.g., aluminum) is then deposited on the material for the lower layer film 71. The material for the upper layer film 73 (e.g., TiN or TiAlN) is deposited on the material for the core part 72. The material for the lower layer film 71 is provided as a diffusion preventing film preventing the metallic material of the core part 72 from diffusing toward the ferroelectric capacitor FC. The material for the upper layer film 73 is provided as a reflection preventing film suppressing reflection during lithography when the second upper electrode UE2 is processed. Thus, misalignment during lithography is suppressed and the second upper electrode UE2 is processed easily.

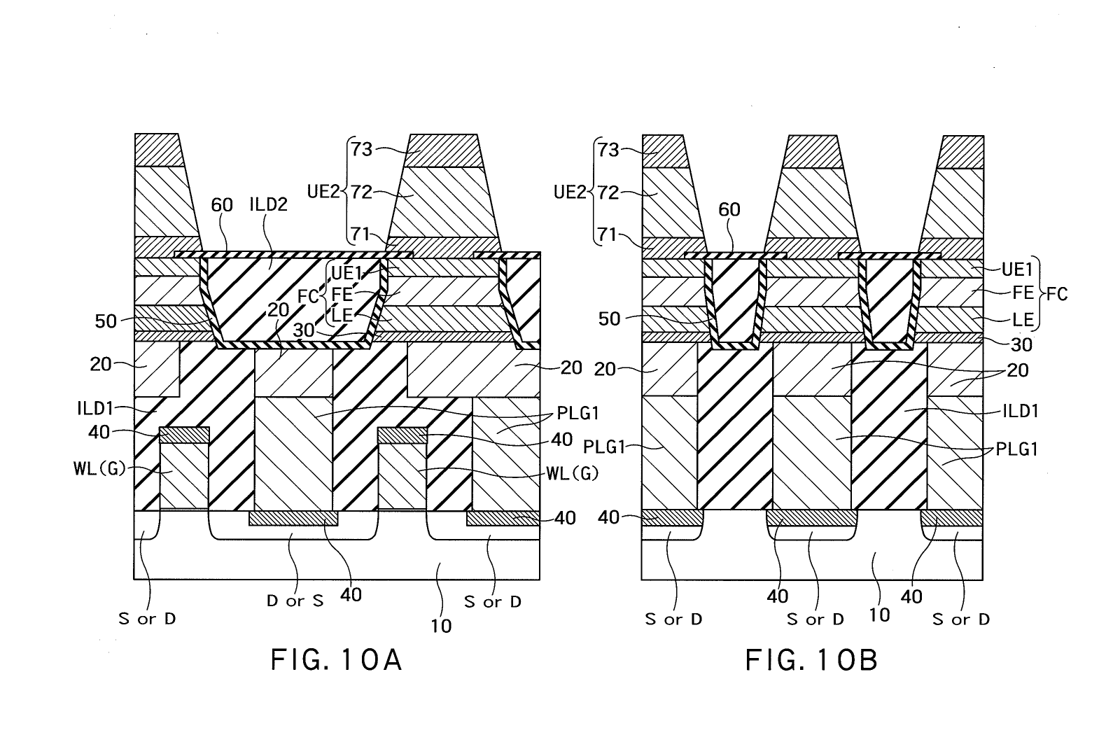

The materials for the upper layer film 73, the core part 72, and the lower layer film 71 are then etched by lithography and RIE. As shown in FIGS. 10A and 10B, the second upper electrode UE2 is formed on the first upper electrode UE1 in order to correspond to the respective ferroelectric capacitors FC. At this time, the side surface of the second upper electrode UE2 is formed in a forward tapered shape.

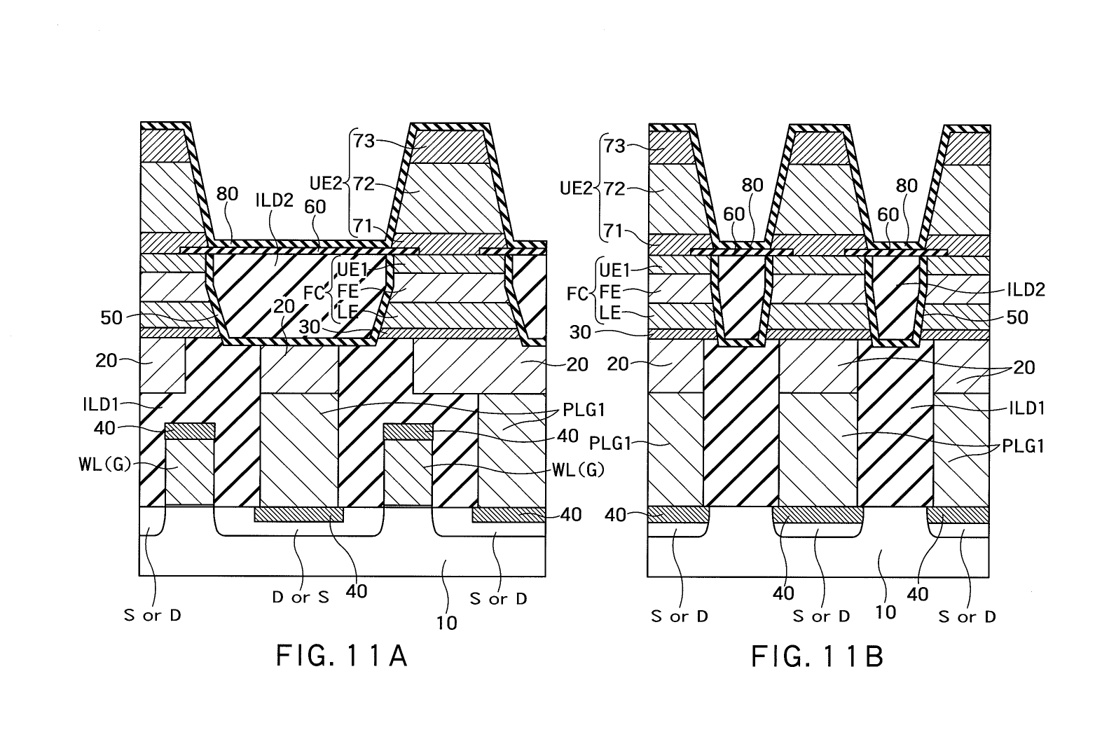

As shown in FIGS. 11A and 11B, the hydrogen barrier film 80 is deposited on the hydrogen barrier film 60 and the top and side surfaces of the second upper electrode UE2.

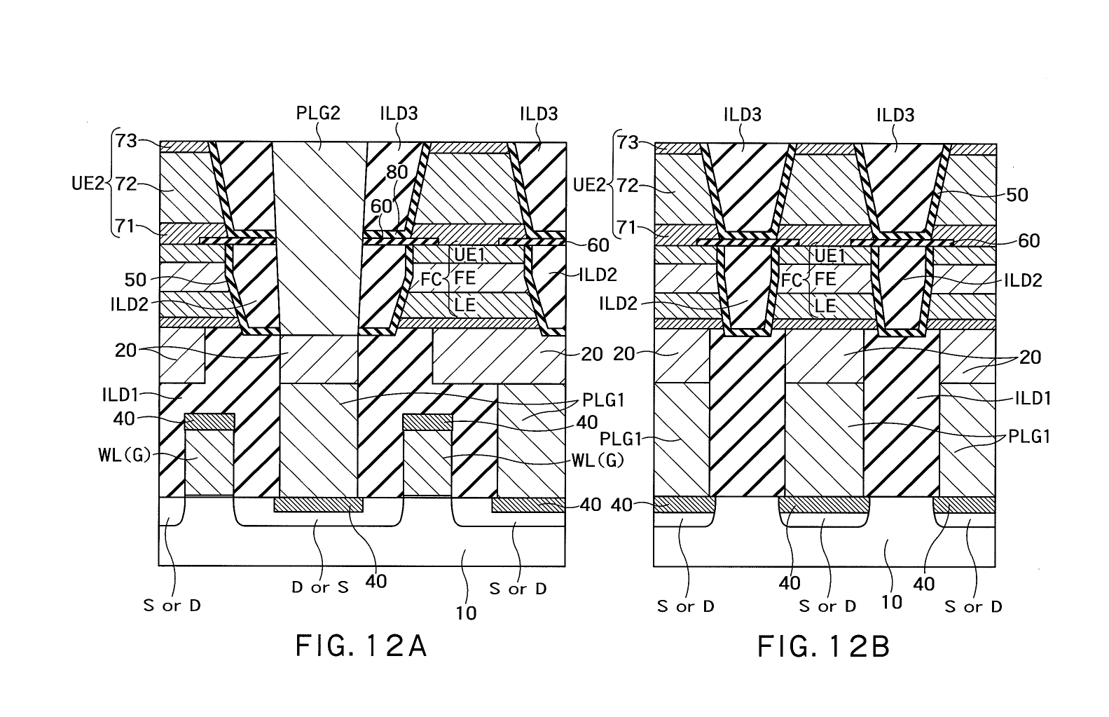

The third interlayer dielectric film ILD3 is then loaded between two second upper electrodes UE2 adjacent to each other in the direction the bit line BL extends. Further, as shown in FIGS. 12A and 12B, a contact hole passing through the third interlayer dielectric film ILD3, the hydrogen barrier films 80 and 60, and the second interlayer dielectric film ILD2 to reach the metallic plug 20 is formed. A metallic material (e.g., tungsten or aluminum) is buried in the contact hole by MO-CVD. The metallic material is then ground by CMP, so that the second contact plug PLG2 is formed.

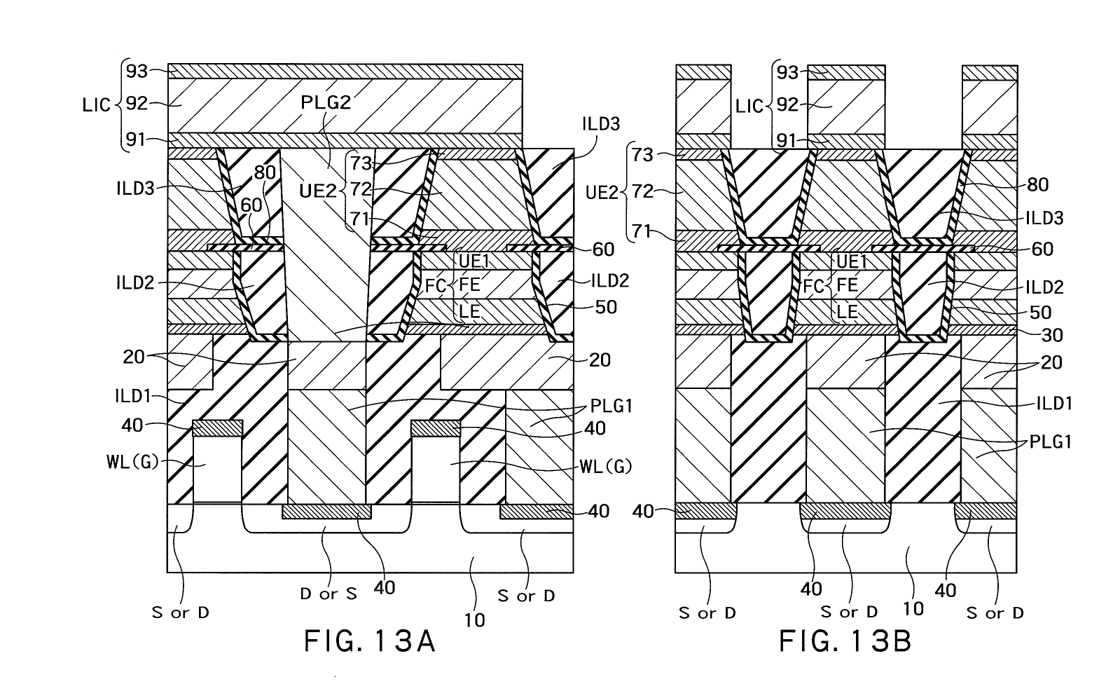

Next, as shown in FIGS. 13A and 13B, materials for the lower layer film 91 (e.g., TiN or TiAlN), the core part 92 (e.g., copper or aluminum), and the upper layer film 93 (e.g., TiN or TiAlN) are deposited on the third interlayer dielectric film ILD3, the second contact plug PLG2, and the second upper electrode UE2. The materials for the lower layer film 91, the core part 92, and the upper layer film 93 are then processed by lithography and RIE. In this way, the local interconnection LIC is formed.

An interlayer dielectric film (not shown) is then deposited on the local interconnection LIC and a bit line contact is formed in that interlayer dielectric film. The bit line is formed on the bit line contact. Thus, the ferroelectric RAM of the first embodiment is completed.

According to the first embodiment, the second upper electrode UE2 connecting between the ferroelectric capacitor FC and the local interconnection LIC is processed into a pillar shape by lithography and RIE without using the damascene process. The hydrogen barrier film 60 much thinner than the interlayer dielectric film is merely etched to connect the second upper electrode UE2 to the first upper electrode UE1. Thus, the deterioration of the signal difference between the data “0” and “1” can be suppressed because the amount of over etching for the top surface of the first upper electrode UE1 is reduced.

Because the first embodiment does not use the damascene process, devices for burying metals in contact holes with high aspect ratio are not required, resulting in suppressed manufacturing costs.

The second upper electrode UE2 is made of a material with inherent tensile stress serving as the core part 72 (e.g., aluminum). Accordingly, even if the polarization state of the ferroelectric film FE changes so that the deposition of the ferroelectric film FE changes, the core part 72 can absorb the depositional change of the ferroelectric film FE. Thus, the deterioration of polarization characteristics of the ferroelectric film FE can be suppressed.

### Second Embodiment

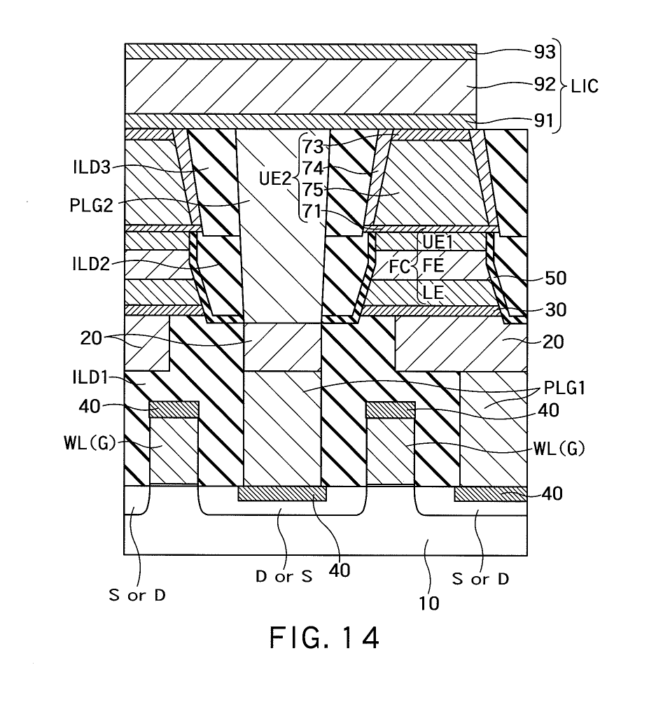

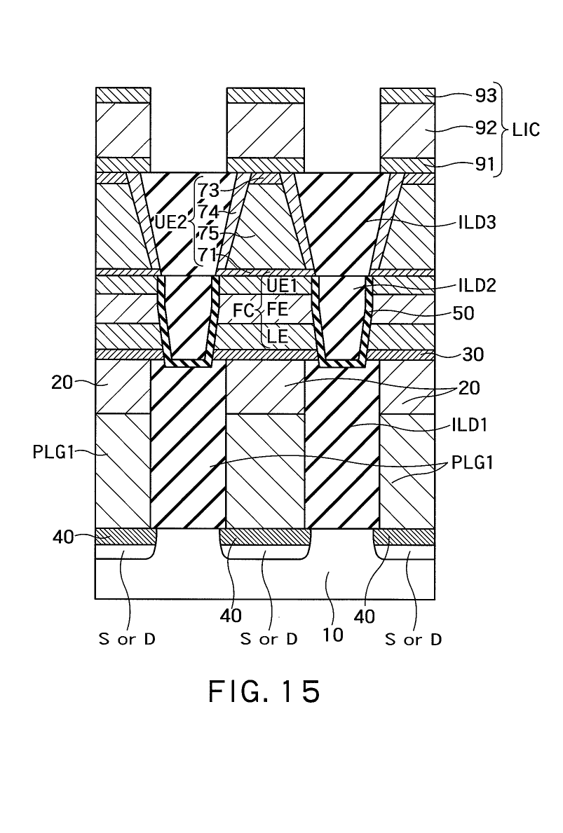

FIGS. 14 and 15 are cross-sectional views showing a configuration of a ferroelectric RAM according to a second embodiment of the present invention. FIG. 14 shows the cross-sectional view along the direction the bit line BL extends, and FIG. 15 shows the cross-sectional view along the direction the word line WL extends.

The second embodiment is different from the first embodiment in the configuration of the second upper electrode UE2. Other configurations of the second embodiment can be identical to those of the first embodiment. The second upper electrode UE2 of the second embodiment comprises a conductive lower layer film 71 on the first upper electrode UE1, a core part 75 on the lower layer film 71, a conductive upper layer film 73 on the core part 75, and a side conductive film 74 that is formed on the side surface of the core part 75 and connects between the upper layer film 73 and the lower layer film 71.

The lower layer film 71, the upper layer film 73, and the side conductive film 74 are conductive hydrogen barrier films and made of TiN or TiAlN, for example. The core part 75 is made of an insulation film such as TEOS.

A manufacturing method of the second embodiment is different from that of the first embodiment in formation of the second upper electrode UE2. Accordingly, only the formation of the second upper electrode UE2 will be described. After the ferroelectric capacitor FC is formed as shown in FIGS. 7A and 7B, materials for the lower layer film 71 (e.g., TiN or TiAlN), the core part 75 (e.g., TEOS), and the upper layer film 73 (e.g., TiN or TiAlN) are deposited on the first upper electrode UE1. A laminated film made of the materials for the upper layer film 73 and the core part 75 is then etched in patterns of the ferroelectric capacitors FC by lithography and RIE. At this time, the lower layer film 71 is not etched yet.

The material for the side conductive film 74 is then deposited in order to cover top and side surfaces of a pillar formed of the core part 75 and the upper layer film 73. The side conductive film 74 is etched back, so that the material for the side conductive film 74 remains on the side surface of the pillar. At the same time, the material for the lower layer film 71 is further etched by using the side conductive film 74 as a mask. As a result, the pillar formed of the lower layer film 71, the core part 75, the upper layer film 73, and the side conductive film 74 are formed on each of the ferroelectric capacitors FC. The side conductive film 74 electrically connects between the lower layer film 71 and the upper layer film 73 along the side surface of the core part 75. In this way, the second upper electrode UE2 of the second embodiment is formed.

Because the material for the lower layer film 71 is etched by using the side conductive film 74 as a mask, the side conductive film 74 can keep contact with the lower layer film 71 at its end.

Because the core part 75 is made of an insulation film such as TEOS in the second embodiment, the lower layer film 71 can serve as an etching stopper for the core part 75. Thus, the lower layer film 71 is formed on the first upper electrode UE1 and the hydrogen barrier film 60 shown in FIGS. 7A and 7B is unnecessary. Further, contact holes do not need to be formed on the first upper electrode UE1. Hollowing out caused by etching the first upper electrode UE1 is further suppressed in the second embodiment. The second embodiment can further achieve identical effects as those of the first embodiment.

### Third Embodiment

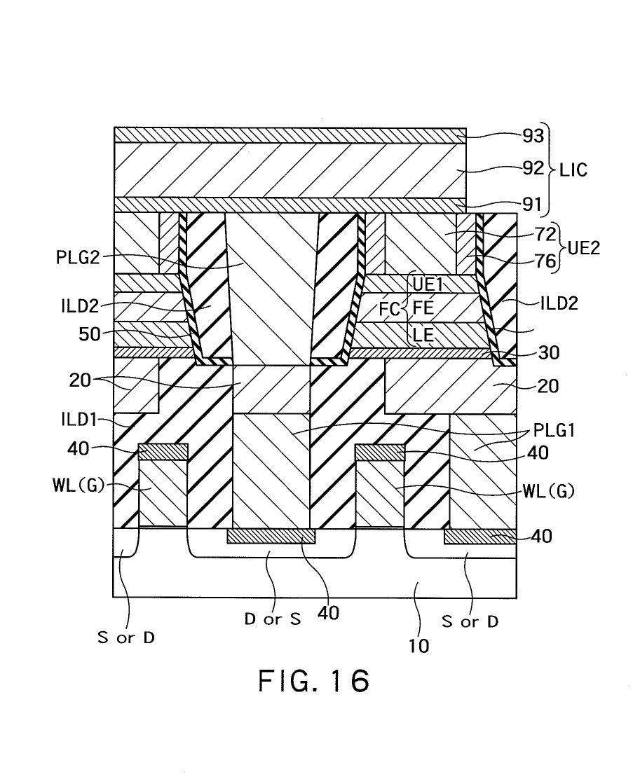

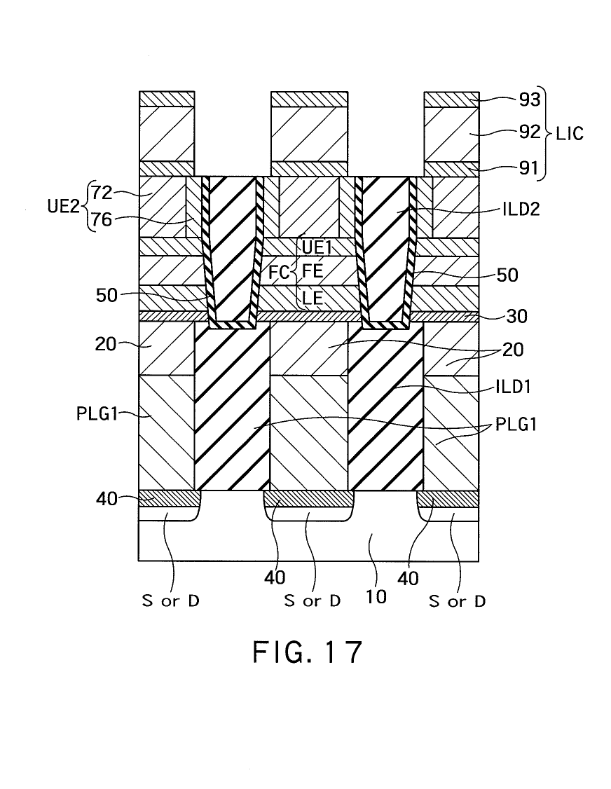

FIGS. 16 and 17 are cross-sectional views showing a configuration of a ferroelectric RAM according to a third embodiment of the present invention. FIG. 16 shows the cross-sectional view along the direction the bit line BL extends. FIG. 17 shows the cross-sectional view along the direction the word line WL extends.

The third embodiment is different from the first embodiment in the configuration of the second upper electrode UE2. Other configurations of the third embodiment can be identical to those of the first embodiment. The second upper electrode UE2 of the third embodiment comprises a core part 72 made of a conductive material on the first upper electrode UE1 and a side wall film 76 on the side surface of the core part 72. A plane pattern of the second upper electrode UE2 is substantially the same as or similar to that of the first upper electrode UE1. That is, the bottom surface of the second upper electrode UE2 coincides substantially with the top surface of the first upper electrode UE1. The side surface of the second upper electrode UE2 is continuous with the side surface of the first upper electrode UE1 without any processes. The core part 72 is a conductive material and made of metal such as aluminum. The side wall film 76 is made of an insulation film such as Al₂O₃.

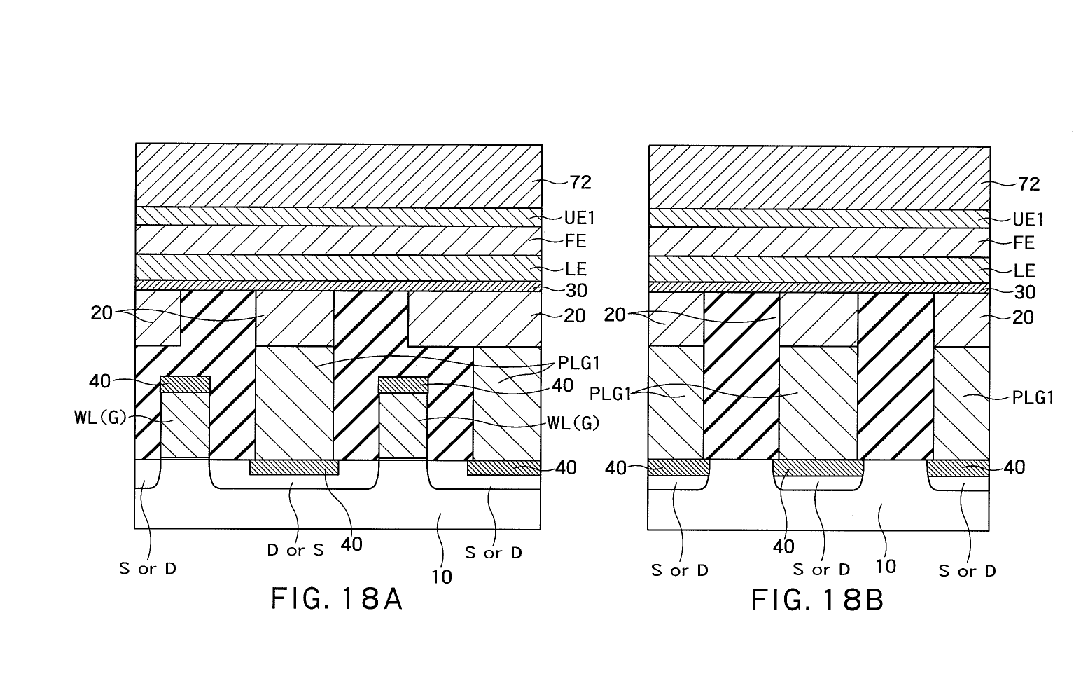

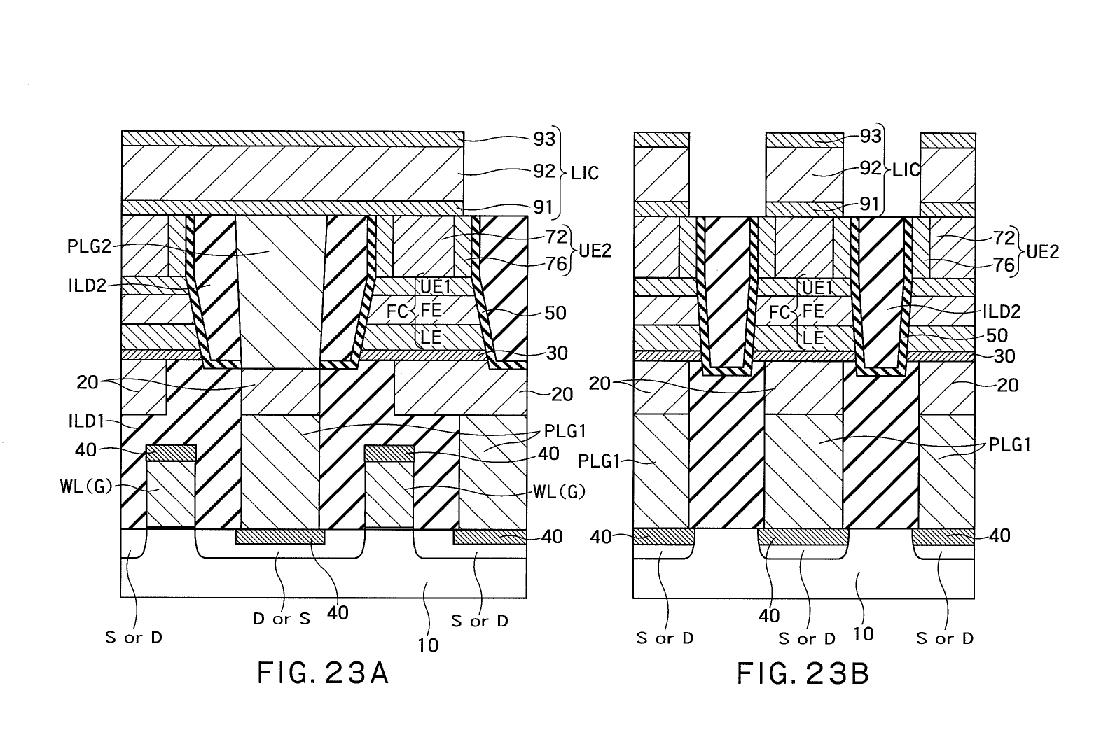

FIGS. 18A to 23B are cross-sectional views showing a manufacturing method of the third embodiment. FIGS. 18 to 23 with a letter A attached thereto show the cross-sections along the bit line BL (corresponding to FIG. 16), and FIGS. 18 to 23 with a letter B attached thereto show the cross-sections along the word line WL (corresponding to FIG. 17).

After the material for the first upper electrode UE1 is deposited as shown in FIGS. 4A and 4B, the material for the core part 72 (e.g., aluminum) is deposited on the material for the first upper electrode UE1 as shown in FIGS. 18A and 18B.

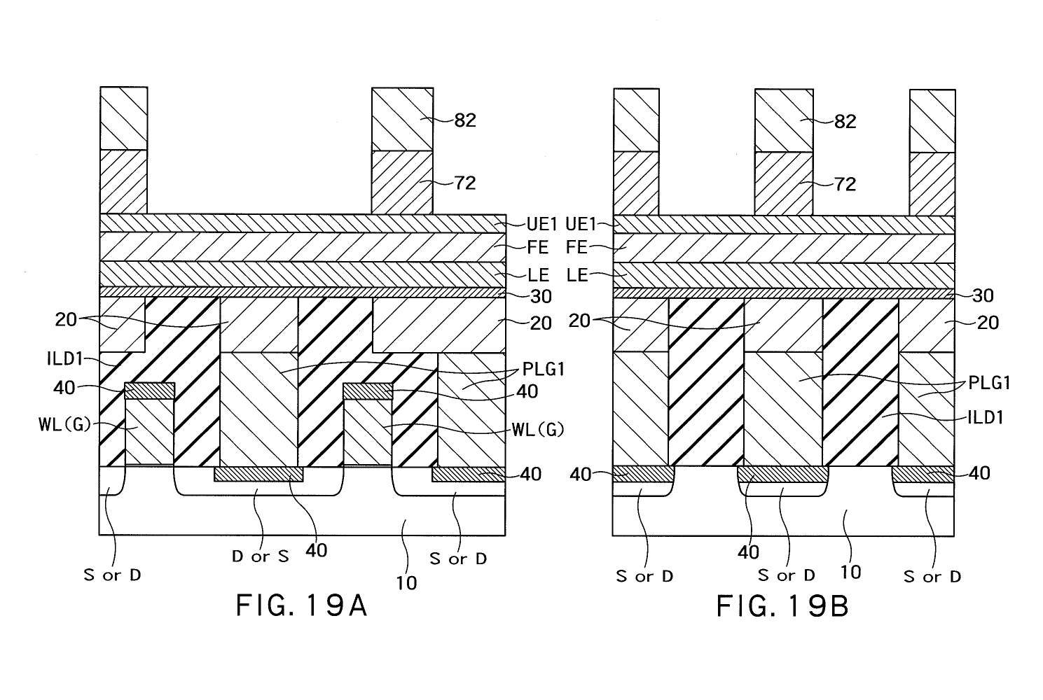

A mask material 82 (e.g., TEOS or silicon nitride film) is deposited on the core part 72. The mask material 82 is then processed in a pattern of the ferroelectric capacitor FC by lithography and RIE. As shown in FIGS. 19A and 19B, the core part 72 is etched with RIE by using the mask material 82 as a mask.

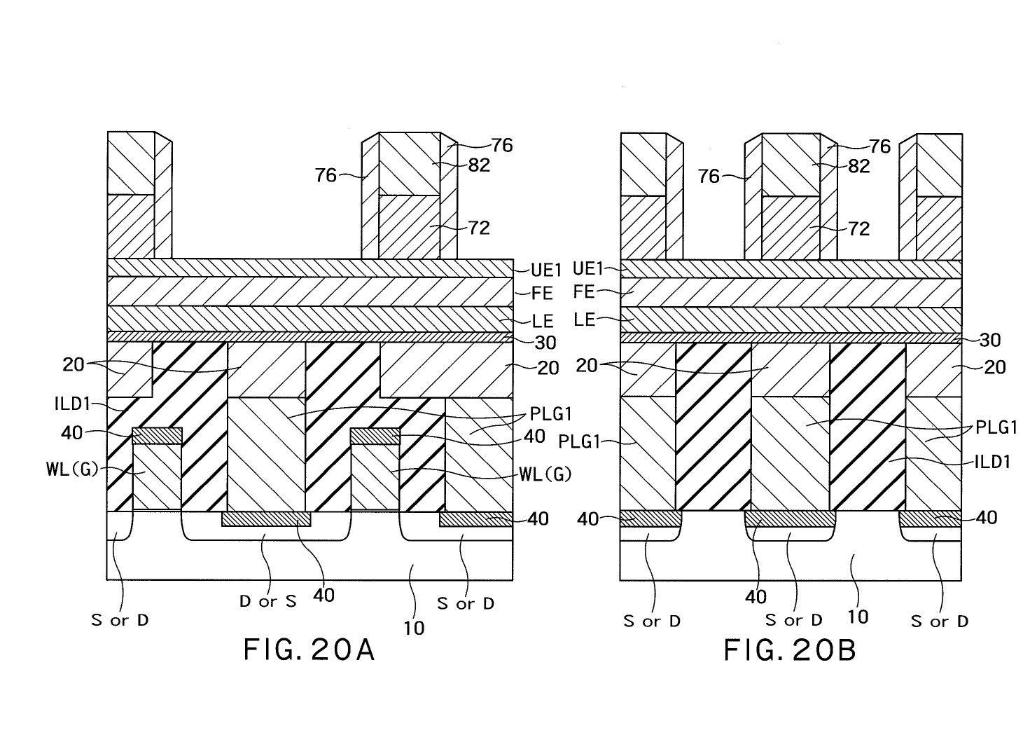

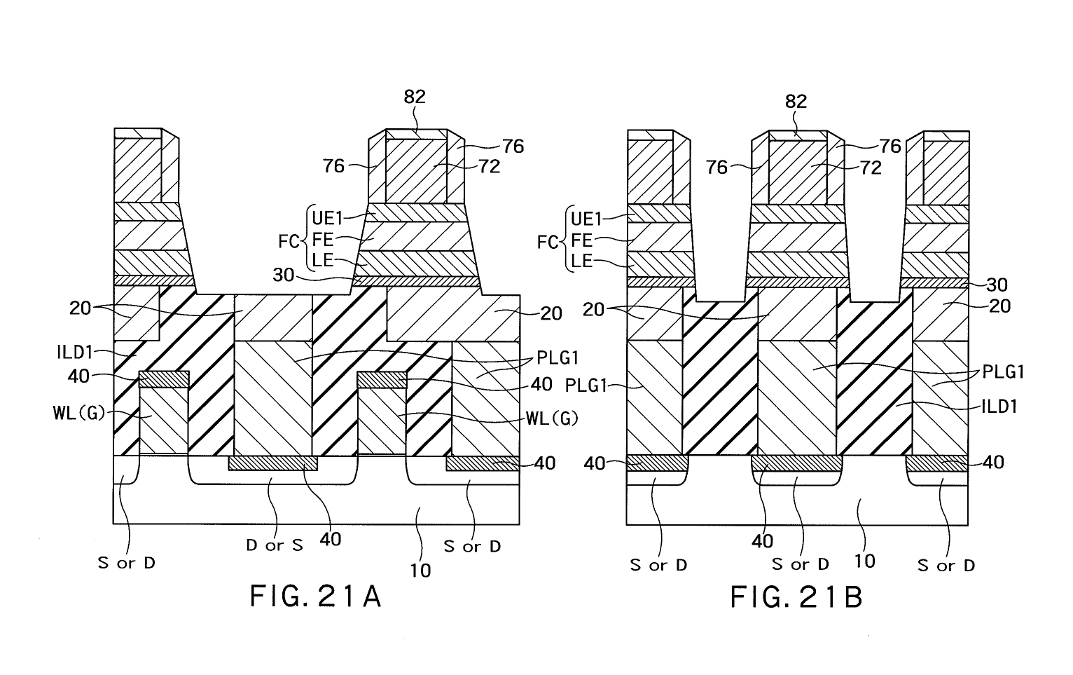

As shown in FIGS. 20A and 20B, the side wall film 76 is formed on the side surfaces of the mask material 82 and the core part 72. The materials for the first upper electrode UE1, the ferroelectric film FE, and the lower electrode LE serving as materials for the ferroelectric capacitor are etched by using the mask material 82 and the side wall film 76 as a mask. Thus, the ferroelectric capacitor FC is formed as shown in FIGS. 21A and 21B. The core part 72 and the side wall film 76 formed on the first upper electrode UE1 become the second upper electrode UE2. According to the third embodiment, the ferroelectric capacitor FC can be formed in a self-aligned manner by using the second upper electrode UE2 as a mask.

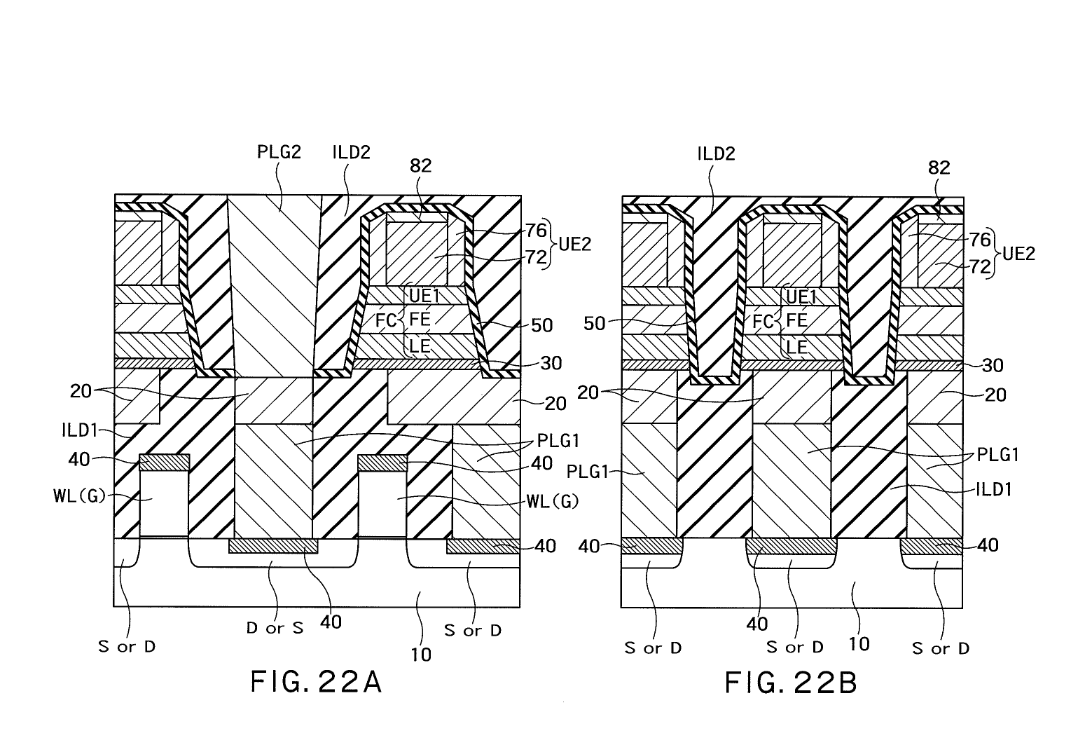

A dielectric hydrogen barrier film 50 (e.g., Al₂O₃) is then deposited on the side surfaces of the ferroelectric capacitor FC and the second upper electrode UE2 and the top surfaces of the mask material 82, the first interlayer dielectric film ILD1, and the metallic plug 20. Further, the second interlayer dielectric film ILD2 is loaded between ferroelectric capacitors FC adjacent to each other in the direction the bit line BL extends and between second upper electrodes UE2 adjacent to each other in the direction the bit line BL extends. After the second interlayer dielectric film ILD2 is flattened by CMP, the second contact plug PLG2 is formed by the damascene process. Configurations shown in FIGS. 22A and 22B are thus obtained.

Next, the hydrogen barrier film 50 and the mask material 82 are ground by CMP until the core part 72 is exposed. The local interconnection LIC is formed on the core part 72 and the second contact plug PLG2. Bit line contacts and bit lines are then formed like the manufacturing method of the first embodiment, so that the ferroelectric RAM of the third embodiment is completed.

According to the third embodiment, the material for the second upper electrode UE2 is deposited directly on the material for the ferroelectric capacitor FC and the second upper electrode UE2 is patterned. The ferroelectric capacitor FC is then formed in a self-aligned manner by using the second upper electrode UE2 as a mask. Thus, the hydrogen barrier film 60 is not required in the third embodiment. Contact holes do not need to be formed on the first upper electrode UE1. As a result, hollowing out caused by etching the first upper electrode UE1 is further suppressed in the third embodiment. The third embodiment can further achieve identical effects as those of the first embodiment.

### Fourth Embodiment

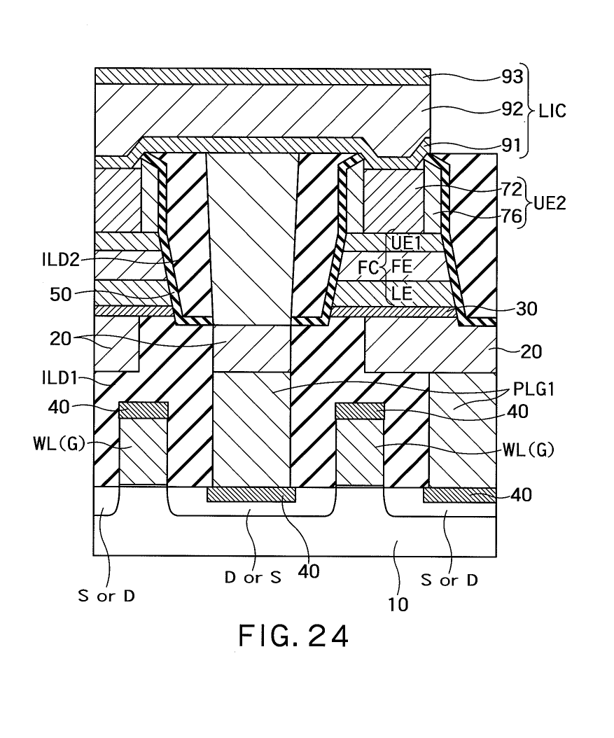

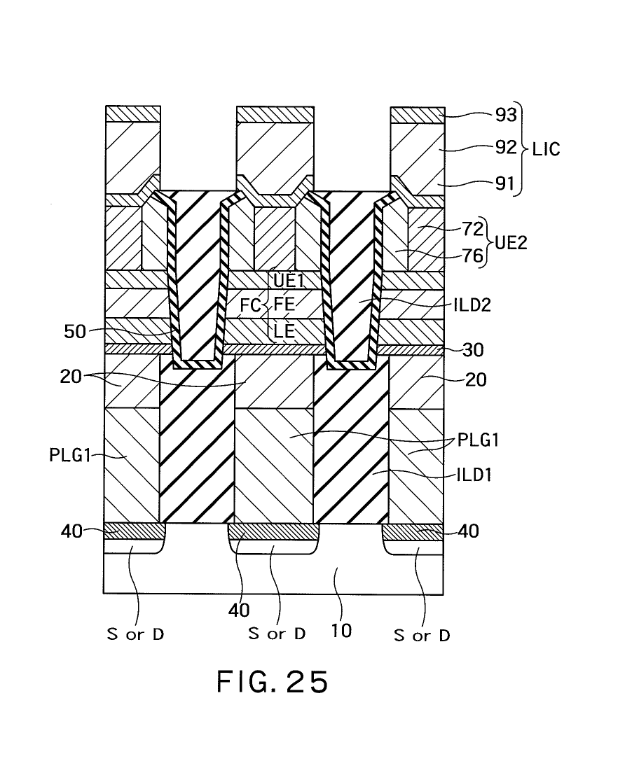

FIGS. 24 and 25 are cross-sectional views showing a configuration of a ferroelectric RAM according to a fourth embodiment of the present invention. FIG. 24 shows the cross-sectional view along the direction the bit line BL extends, and FIG. 25 shows the cross-sectional view along the direction the word line WL extends.

The fourth embodiment is different from the third embodiment in the contact between the second upper electrode UE2 and the local interconnection LIC. Other configurations of the fourth embodiment can be identical to those of the third embodiment.

After the configurations shown in FIGS. 22A and 22B are formed, a contact hole is formed on the second upper electrode UE2 by lithography and RIE. The top surface of the core part 72 is thus exposed. The local interconnection LIC is formed as described in the first embodiment. Bit line contacts and bit lines are then formed like the manufacturing method of the first embodiment, so that the ferroelectric RAM of the fourth embodiment is completed.

The contact hole is formed on the second upper electrode UE2 in the fourth embodiment. Even if the material for the local interconnection LIC is deposited, the position of the second upper electrode UE2 can be found. Thus, lithography misalignment can be prevented when the local interconnection LIC is formed. The fourth embodiment can further achieve identical effects as those of the third embodiment.

1. A semiconductor memory device comprising:
a transistor on a semiconductor substrate;
an interlayer dielectric film on the transistor;
a ferroelectric capacitor comprising a first upper electrode, a ferroelectric film, and a lower electrode above the interlayer dielectric film;
a contact plug in the interlayer dielectric film and configured to electrically connect the lower electrode to the transistor;
a second upper electrode on the first upper electrode, a side surface of the second upper electrode comprising a forward tapered shape; and
an interconnection electrically connected to the first upper electrode via the second upper electrode.

2. The device of claim 1, further comprising a contact plug connecting the interconnection to the transistor.

3. The device of claim 1, wherein
the second upper electrode comprises:
a conductive diffusion preventing film on the first upper electrode;
a metallic film on the diffusion preventing film, the metallic film containing tensile stress; and
a reflection preventing film on the metallic film, wherein
the diffusion preventing film is configured to suppress diffusion of a material from the metallic film toward the ferroelectric capacitor, and
the reflection preventing film is configured to suppress reflection from the metallic film during a lithography process when processing the second upper electrode.

4. The device of claim 1, wherein
the second upper electrode comprises:
a conductive hydrogen barrier film on the first upper electrode;
an insulation film on the hydrogen barrier film;
an upper conductive film on the insulation film; and
a side conductive film on a side surface of the insulation film and is configured to connect between the upper conductive film and the hydrogen barrier film.

5. The device of claim 1, wherein
the second upper electrode comprises:
a conductive film on the first upper electrode; and
an insulation film on a side surface of the conductive film, wherein
a plane pattern of the second upper electrode is similar to that of the first upper electrode.

6. The device of claim 1, wherein
the second upper electrode comprises:
a conductive film on the first upper electrode; and
an insulation film on a side surface of the conductive film, wherein
a side surface of the second upper electrode is continuous with a side surface of the first upper electrode.

7. A manufacturing method of a semiconductor memory device, comprising:
forming a plurality of transistors on a semiconductor substrate;
forming a first interlayer dielectric film covering the transistors;
forming a plurality of first contact plugs passing through the first interlayer dielectric film to be connected to the transistors;
forming a plurality of ferroelectric capacitors each of which comprises a first upper electrode, a ferroelectric film, and a lower electrode above one of the first contact plugs;
forming a second interlayer dielectric film between adjacent ferroelectric capacitors;
depositing a second upper electrode material on the first upper electrode and the second interlayer dielectric film;
processing the second upper electrode material to form a second upper electrode on each of the first upper electrodes;
forming a third interlayer dielectric film between the adjacent second upper electrodes;
forming a second contact plug passing through the third and the second interlayer dielectric films to be electrically connected to the transistor; and
forming an interconnection on the third interlayer dielectric film, the second upper electrode, and the second contact plug.

8. The method of claim 7, wherein the forming of the second upper electrode comprises:
forming a hydrogen barrier film on the first upper electrode and the second interlayer dielectric film;
exposing a part of the first upper electrode by processing the hydrogen barrier film;
depositing a conductive diffusion preventing film suppressing diffusion of metal on the first upper electrode;
depositing a conductive metallic film containing tensile stress on the diffusion preventing film;
depositing a conductive reflection preventing film to suppress reflections from the metallic film during processing of the metallic film; and
processing the reflection preventing film, the metallic film, and the diffusion preventing film to form the second upper electrode comprising the reflection preventing film, the metallic film, and the diffusion preventing film.

9. The method of claim 7, wherein the forming of the second upper electrode comprises:
depositing a conductive hydrogen barrier film on the first upper electrode;
depositing an insulation film on the hydrogen barrier film;
depositing an upper conductive film on the insulation film;
processing the upper conductive film and the insulation film into a pattern of the ferroelectric capacitor; and
forming a side conductive film connecting between the hydrogen barrier film and the upper conductive film on side surfaces of the upper electrode and the insulation film, and simultaneously etching the hydrogen barrier film by using the upper electrode and the side conductive film as a mask.

10. A manufacturing method of a semiconductor memory device, comprising:
forming a plurality of transistors on a semiconductor substrate;
forming a first interlayer dielectric film covering the transistors;
forming a plurality of first contact plugs passing through the first interlayer dielectric film to be connected to the transistors;
depositing materials of ferroelectric capacitors each of which comprises a first upper electrode, a ferroelectric film, and a lower electrode above one of the first contact plugs;
depositing a second upper electrode material on the first upper electrode;
depositing a mask material on the second upper electrode material;
processing the mask material into a pattern of the second upper electrode;
forming sidewall films on side surfaces of the mask material and the second upper electrode; and
etching the materials of the ferroelectric capacitors using the mask material and the sidewall films as a mask to form a plurality of ferroelectric capacitors.
